(19) United States
(12) Patent Application Publication
(10) Pub. No.: US 2014/0264808 A1
(43) Pub. Date: Sep. 18, 2014

(54) CHIP ARRANGEMENTS, CHIP PACKAGES, AND A METHOD FOR MANUFACTURING A CHIP ARRANGEMENT

(71) Applicants: Andreas Wolter, Regensburg (DE); Thorsten Meyer, Regensburg (DE)

(72) Inventors: Andreas Wolter, Regensburg (DE); Thorsten Meyer, Regensburg (DE)

(21) Appl. No.: 13/832,200

(22) Filed: Mar. 15, 2013

(51) Int. Cl. H01L 23/48; H01L 21/56

(52) U.S. Cl. CPC H01L 23/481; H01L 21/56
USPC 257/678; 257/774; 438/127

(57) ABSTRACT

A chip arrangement may include a semiconductor chip; an encapsulation layer at least partially encapsulating the semiconductor chip, the encapsulation layer having a receiving region configured to receive an electronic device, the receiving region comprising a cavity; and an electronic device disposed in the receiving region.

### TECHNICAL FIELD

Various aspects relate to chip arrangements, chip packages, and a method for manufacturing a chip arrangement.

### BACKGROUND

In manufacturing integrated circuits (ICs), the ICs, which may also be referred to as chips or dies, may be packaged prior to distribution and/or integration with other electronic assemblies. This packaging may include encapsulating the chips in a material, and providing electrical contacts on the exterior of the package to provide an interface to the chip. Chip packaging, amongst other things, may provide protection from ambient atmosphere or contaminants, provide mechanical support, disperse heat, and reduce mechanical damage.

As the demand for greater capabilities and features of ICs increases, chips including, for example, sensors, oscillators, and micro-electromechanical systems (MEMs) may be included in IC packages. Such chips may, for example, require free headroom so as to function properly and/or may be adversely affected by stress (e.g. mechanical stress) in the IC package. Accordingly, current IC packages may not be suitable for such chips and new ways of packaging such chips may be needed.

### SUMMARY

A chip arrangement is provided, which may include: a semiconductor chip; an encapsulation layer at least partially encapsulating the semiconductor chip, the encapsulation layer having a receiving region configured to receive an electronic device, the receiving region comprising a cavity; and an electronic device disposed in the receiving region.

A chip package is provided, which may include: a semiconductor chip; an encapsulation layer at least partially encapsulating the semiconductor chip; a cavity disposed in the encapsulation layer; and an electronic device disposed in the cavity and electrically coupled to the semiconductor chip.

A chip package is provided, which may include: a semiconductor chip; an encapsulation layer at least partially encapsulating the semiconductor chip; a cavity disposed in the encapsulation layer; and an electronic device disposed over the cavity and configured to seal the cavity, and electrically coupled to the semiconductor chip.

A method for manufacturing a chip arrangement is provided, which may include: providing a semiconductor chip; forming an encapsulation layer to at least partially encapsulate the semiconductor chip; forming a cavity in the encapsulation layer; and disposing an electronic device in or over the cavity.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows a cross-sectional view of an embedded wafer level ball grid array package.

FIG. 2 shows a cross-sectional view of a chip arrangement.

FIG. 3 shows a cross-sectional view of a chip arrangement including a redistribution layer which is fully disposed in a cavity.

FIG. 4 shows a cross-sectional view of a chip arrangement including at least one flip chip interconnect disposed in a cavity and coupling an electronic device to a redistribution layer.

FIG. 5 shows a cross-sectional view of a chip arrangement including at least one through-mold-via disposed in an encapsulation layer between a semiconductor chip and a cavity.

FIG. 6 shows a cross-sectional view of a chip arrangement including at least one flip chip interconnect which may be in contact with a surface of a semiconductor chip.

FIG. 7 shows a cross-sectional view of a chip arrangement including a semiconductor chip and a cavity disposed at a same side of an encapsulation layer.

FIG. 8 shows a cross-sectional view of a chip arrangement including an electronic device disposed over a cavity.

FIG. 9 shows a plan view of an encapsulation layer, an anisotropic conductive adhesive, and a cavity coated with a sealing layer, prior to disposing an electronic device over the cavity.

FIG. 10 shows a cross-sectional view of a chip arrangement including at least one bonding wire connecting an electronic device and at least one through-mold-via.

FIG. 11 shows a method for manufacturing a chip arrangement.

### DESCRIPTION

The following detailed description refers to the accompanying drawings that show, by way of illustration, specific details and aspects in which the invention may be practised. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects can be combined with one or more other aspects to form new aspects. Various aspects are described for structures or devices, and various aspects are described for methods. It may be understood that one or more (e.g. all) aspects described in connection with structures or devices may be equally applicable to the methods, and vice versa.

The word “exemplary” is used herein to mean “serving as an example, instance, or illustration”. Any aspect or design described herein as “exemplary” is not necessarily to be construed as preferred or advantageous over other aspects or designs.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

The terms “coupled” and/or “electrically coupled” and/or “connected” and/or “electrically connected”, used herein to describe a feature being connected to at least one other implied feature, are not meant to mean that the feature and the at least one other implied feature must be directly coupled or connected together; intervening features may be provided between the feature and at least one other implied feature.

Directional terminology, such as e.g. “upper”, “lower”, “top”, “bottom”, “left-hand”, “right-hand”, etc., may be used with reference to the orientation of figure(s) being described. Because components of the figure(s) may be positioned in a number of different orientations, the directional terminology is used for purposes of illustration and is in no way limiting. It is to be understood that structural or logical changes may be made without departing from the scope of the invention.

Chips (which may also be referred to as “dies”) may have to be packaged prior to distribution and/or integration with other electronic devices, such as circuit boards (e.g. printed circuit boards), other chips and/or other chip packages. Packaging a chip (or die) may include encapsulating the chip in a material (e.g. a plastic material), and providing electrical contacts (e.g. solder balls) at a surface (e.g. an exterior surface) of the package. The electrical contacts (e.g. solder balls) provided at the surface of the chip package may provide an interface for the chip. For example, the package may be connected to a PCB (printed circuit board) by means of the electrical contacts (e.g. solder balls). By way of another example, other chip packages and/or electronic devices may be connected (e.g. electrically connected) to the chip via the electrical contacts (e.g. solder balls).

FIG. 1 shows a cross-sectional view of an embedded wafer level ball grid array (eWLB) package 100.

The eWLB package 100 may include a chip 102 (or die), a plurality of solder balls 106, a redistribution layer 108, and an encapsulation 112.

The chip 102 (or die) may include a plurality of conductive pads 104, which may be formed on a surface (e.g. a frontside or a bottom surface) of the chip 102. The chip 102 may be electrically connected to at least one solder ball of a plurality of solder balls 106 by means of a redistribution layer (RDL) 108. For example, the RDL 108 may redistribute and/or re-map electrical connections from the plurality of conductive pads 104 to the plurality of solder balls 106 (which may also be referred to as a ball grid array (BGA) of solder balls 106).

The eWLB package 100 may include an insulating layer 110 (e.g. a dielectric layer), which may be configured to insulate (e.g. electrically insulate) a surface 100a (e.g. a frontside) of the eWLB package 100. The RDL 108 may, for example, be disposed fully or partially within the insulating layer 110. The insulating layer 110 may include a dielectric layer that may be disposed between the chip 102 and the RDL 108. The insulating layer 110 may include a solder-stop layer that may be disposed at a surface of the RDL 108 and a surface of the dielectric layer facing away from the chip 102. The dielectric layer of the insulating layer 110 may include, or may consist of, at least one material that may be different from the solder-stop layer of the insulating layer 110. An encapsulation 112 (e.g. including, or consisting of, a molding material, for example, a polymer material) may be formed (e.g. molded) around the chip 102. For example, the encapsulation 112 may be formed at surfaces of the chip 102 facing away from the RDL 108, and may encapsulate the chip 102. For example, the encapsulation 112 may be formed at or over a surface of the chip 102 facing away from the RDL 108, and at or over at least one sidewall of the chip 102. For example, the encapsulation 112 may enclose the chip 102, as shown in FIG. 1. By way of another example, the encapsulation 112 may enclose the chip 102 from the surface of the chip 102 facing away from the RDL 108 and from all sidewalls of the chip 102. In other words, the chip 102 may be enclosed from five of its sides in the encapsulation 112.

The eWLB package 100 may form a single package, which may have an interface provided by the BGA of solder balls 106. For example, electrical signals and/or potentials may be exchanged with the chip 102 of the eWLB package via the BGA of solder balls 106. The BGA of solder balls 106 may be electrically coupled to (e.g. soldered to) a circuit board such as, for example, a printed circuit board (PCB). In other words, the eWLB package 100 may be placed on a circuit board (e.g. a PCB) as part of a larger circuit and/or device.

The encapsulation 112 may, for example, protect the chip 102 of the eWLB package 100 from contaminants and/or moisture that may be present in the ambient atmosphere. Additionally, or alternatively, the encapsulation 112 may, for example, protect the chip 102 from mechanical damage that may be caused by a force that may be exerted on the eWLB package 100.

However, thermo-mechanical stresses may occur inside the eWLB package 100. For example, the chip 102 and/or other components of the eWLB package 100 may be subjected to thermo-mechanical stress during the manufacture of the eWLB package 100. For example, volume changes that may occur during the manufacture of the eWLB package 100 (e.g. during cross-linking of polymers of the encapsulation 112) may induce mechanical stresses on the chip 102.

By way of another example, manufacturing the eWLB package 100 may require a use of high temperatures, which may subject the chip 102 to thermal stresses.

By way of yet another example, stresses caused by aging of a material (e.g. a material of the encapsulation 112) over a lifetime of the eWLB package 100 may induce stresses on the chip 102.

Furthermore, the eWLB package 100 may be placed on (e.g. soldered to) a circuit board (e.g. a PCB), and may be subjected to thermo-mechanical stresses induced by, for example, external forces exerted on the circuit board.

The encapsulation 112 may include, or may consist of, a material that may have a high Young's modulus. In other words, the encapsulation 112 may be rigid and may not be able to bend easily. Stated in yet another way, the encapsulation 112 may not be compliant. Therefore, the encapsulation 112 may not be able to compensate for the above-described thermo-mechanical stresses exerted on the chip 102, and this may lead to damage to the chip 102 and/or degraded performance of the chip 102.

The chip 102 may include, or may be, an electronic device that may require free headroom (e.g. a gap) at one or more of its surfaces in order to, for example, ensure proper functioning of the chip 102. For example, free headroom (e.g. a gap) may allow free movement of mechanical parts included in the chip 102. By way of another example, free headroom (e.g. a gap) may decouple (e.g. mechanically and/or acoustically decouple) the chip 102 from other components of the eWLB package 100.

As an illustration, the chip 102 may include, or may be, a mechanical oscillator, which may include one or more oscillating quartz crystals and/or surface acoustic wave (SAW) structures and/or bulk acoustic wave (BAW) structures. The chip 102 (e.g. mechanical oscillator) may require free headroom so as to allow free movement of the oscillating quartz crystals and/or SAW structures and/or BAW structures. Furthermore, as described above, the free headroom may acoustically decouple the chip 102 (e.g. mechanical oscillator) from other structures and/or devices, thus substantially reducing or eliminating a shift in and/or a damping of an oscillation frequency.

Since the encapsulation 112 of the eWLB package 100 may enclose (e.g. fully enclose) the chip 102 (e.g. from five of its sides), the eWLB package 100 may not be suitable for packaging of a chip that may require free headroom (e.g. a gap). Additionally, or alternatively, the eWLB package 100 may not be suitable for packaging a chip that may be sensitive to mechanical stresses exerted on it. Furthermore, or alternatively, the eWLB package 100 may not be suitable for packaging a chip that may require mechanical and/or acoustic decoupling for proper function.

Since the eWLB package 100 may not be suitable for packaging a chip that may require free headroom (e.g. a gap) and/or that may be sensitive to mechanical stresses and/or that may require mechanical and/or acoustic decoupling for proper function, such chips (which may also be referred to as sensitive chips) may be packaged separately. For example, an open cavity package that separately packages a sensitive chip may be used to, for example, provide mechanical decoupling and/or headroom. By way of another example, a sensitive structure (e.g. oscillating quartz crystals and/or SAW structures and/or BAW structures) of a sensitive chip may be decoupled from a body of the sensitive chip (e.g. by means of one or more air gaps). The separately packaged sensitive chip may be subsequently integrated with at least one other device and/or chip by assembling the separately packaged sensitive chip and the at least one other device and/or chip on a printed circuit board (PCB) or a module board, and connecting them via an electrical interconnect.

The above-identified approach may lead to higher manufacturing costs. For example, separately packaging the sensitive chip may increase the overall manufacturing cost. By way of another example, an open cavity package for the sensitive chip may be costly in itself and/or may require more process steps to manufacture.

The above-identified approach may lead to poor electrical performance. For example, the electrical interconnect that may connect (e.g. electrically connect) the separately packaged sensitive chip with at least one other device and/or chip on a PCB or module board may be longer than, for example, a SiP (system in package). This may lead to lower reliability of the electrical interconnects. Furthermore, the longer electrical interconnect may have increased resistance and/or capacity and/or inductivity and thus, poor electrical performance.

The above-identified approach may lead to increased real estate usage. For example, more area on a PCB or module board may be required to integrate the separately packaged sensitive chip with at least one other device and/or chip. This may be in contradistinction with industry demands for minimizing real estate usage and for providing greater capabilities and features in a single IC package.

In light of the above-described undesirable effects of separately packaging a sensitive chip, the following needs may be identified:

There may be a need to package and/or integrate a chip that may be sensitive to thermo-mechanical stresses and/or that may require free headroom (e.g. a gap) with at least one other device in a chip arrangement (e.g. an eWLB package) to realize, for example, a SiP (system-in-package).

There may be a need for a chip package and/or a chip arrangement that may be able to integrate a chip which may be sensitive to thermo-mechanical stresses and/or that may require free headroom (e.g. a gap) in a chip arrangement (e.g. an eWLB package).

There may be a need for a chip package and/or a chip arrangement that may be able to substantially reduce or eliminate mechanical stresses in a chip arrangement (e.g. an eWLB package) that may be exerted against a chip that may be sensitive to thermo-mechanical stresses and/or that may require free headroom (e.g. a gap).

There may be a need to protect and/or seal a chip in a chip arrangement (e.g. in an eWLB package) that may be sensitive to thermo-mechanical stresses and/or that may require free headroom (e.g. a gap) against water, moisture, contaminants or other elements that may be present in the ambient atmosphere which may be detrimental to the chip.

FIG. 2 shows a cross-sectional view of a chip arrangement 200.

The chip arrangement 200 may, for example, be configured as a chip package. The chip arrangement 200 may, for example, be configured as an embedded wafer level ball grid array (eWLB) package. The chip arrangement 200 may, for example, be configured as a system-in-package (SiP).

The chip arrangement 200 may include a semiconductor chip 202, an encapsulation layer 204, and an electronic device 206.

Only one semiconductor chip 202 is shown as an example, however the number of semiconductor chips 202 may be greater than one, and may, for example, be two, three, four, five, etc. In like manner, only one electronic device 206 is shown as an example, however the number of electronic devices 206 may be greater than one, and may, for example, be two, three, four, five, etc.

The semiconductor chip 202 may include, or may be, a chip (or die) for use in logic applications and/or memory applications and/or power applications, although chips for use in other applications may be possible as well. The semiconductor chip 202 may include a semiconductor substrate, which may include, or may consist of, a semiconductor material. The semiconductor material may include, or may be, at least one material selected from a group of materials, the group consisting of: silicon, germanium, gallium nitride, gallium arsenide, and silicon carbide, although other materials may be possible as well.

The semiconductor chip 202 may include a first surface 202a (e.g. a backside or a top surface), a second surface 202b (e.g. a frontside or a bottom surface) opposite the first surface 202a, and at least one sidewall 202c. The semiconductor chip 202 may include at least one pad 202d formed at, for example, the second surface 202b (e.g. frontside or bottom surface). In another example, at least one pad 202d may be formed (e.g. additionally formed) at the first surface 202a (e.g. backside or top surface) of the semiconductor chip 202 (not shown, see e.g. FIG. 5). The at least one pad 202d of the semiconductor chip 202 may, for example, provide an interface (e.g. an electrical interface) for the semiconductor chip 202. In other words, signals (e.g. electrical signals, power supply potentials, ground potentials, etc.) may be exchanged with the semiconductor chip 202 via the at least one pad 202d.

The chip arrangement 200 may include a first redistribution layer (RDL) 210-1. The first RDL 210-1 may, for example, be a frontside RDL of the chip arrangement 200. The semiconductor chip 202 may be disposed over the first RDL 210-1, as shown in FIG. 2. For example, the second surface 202b (e.g. frontside or bottom surface) of the semiconductor chip 202 may face the first RDL 210-1 (e.g. a frontside RDL). The first RDL 210-1 (e.g. frontside RDL) may, for example, be connected (e.g. electrically connected) to the at least one pad 202d of the semiconductor chip 202.

The first RDL 210-1 may include, or may consist of, at least one electrically conductive material. The at least one electrically conductive material may be selected from a group of electrically conductive materials, the group consisting of: a metal or a metal alloy, although other electrically conductive materials may be possible as well. For example, the first RDL 210-1 may include, or may consist of, copper, aluminum, titanium, tungsten, nickel, palladium, gold, or a metal alloy including one or more of the following metals: copper, aluminum, titanium, tungsten, nickel, palladium, and gold.

The first RDL 210-1 may be formed by, for example, at least one of the following processes: sputtering, resist deposition, resist structuring, electroplating, resist stripping, etching, electro-less plating, dispensing, and printing, although other processes may be possible as well.

The chip arrangement 200 may include a plurality of solder balls 212. The plurality of solder balls 212 may also be referred to as a ball grid array (BGA) of solder balls 212. The plurality of solder balls 212 may be formed by, for example, at least one of the following processes: application of preformed solder balls, printing (e.g. a solder paste printing process), solder jetting, and dispensing, although other processes may be possible as well.

The semiconductor chip 202 may be connected (e.g. electrically connected) to at least one solder ball of the plurality of solder balls 212 by means of the first RDL 210-1 (e.g. frontside RDL). For example, the first RDL 210-1 (e.g. frontside RDL) may redistribute and/or re-map electrical connections from the at least one pad 202b of the semiconductor chip 202 to at least one solder ball of the plurality of solder balls 212.

The chip arrangement 200 may include an insulating layer 214 (e.g. a dielectric layer) formed at the second surface 202b (e.g. frontside or bottom surface) of the semiconductor chip 202. The first RDL 210-1 (e.g. frontside RDL) may, for example, be fully or partially disposed within the insulating layer 214 (e.g. a dielectric layer). A surface 214a (e.g. a bottom surface) of the insulating layer 214 facing away from the semiconductor chip 202 may, for example, be a side of the chip arrangement 200. For example, the surface 214a of the insulating layer 214 shown in FIG. 2 may be a frontside of the chip arrangement 200. In such an example, the insulating layer 214 may, for example, be referred to as a frontside insulating layer (e.g. a frontside dielectric layer) of the chip arrangement 200.

The chip arrangement 200 may include an encapsulation layer 204. The semiconductor chip 202 may be disposed at a first side 204a (e.g. a frontside or a bottom surface) of the encapsulation layer 204. For example, the semiconductor chip 202 may be disposed within the encapsulation layer 204, such that the second surface 202b (e.g. a frontside or bottom surface) of the semiconductor chip 202 may be at least substantially flush with the first side 204a (e.g. a frontside or a bottom surface) of the encapsulation layer 204, as shown in FIG. 2. For example, the second surface 202b (e.g. a frontside or bottom surface) of the semiconductor chip 202 and the first side 204a (e.g. a frontside or a bottom surface) of the encapsulation layer 204 may be sufficiently flush to allow a forming of the first RDL 210-1 (e.g. by means of one or more wafer processes). By way of another example, the second surface 202b (e.g. a frontside or bottom surface) of the semiconductor chip 202 may be offset from the first side 204a (e.g. a frontside or a bottom surface) of the encapsulation layer 204 by a distance in the range from about −5 μm to about 15 μm, e.g. about −5 μm, e.g. about 5 μm, e.g. about 15 μm. A positive value of the distance may indicate that the semiconductor chip 202 protrudes from the encapsulation layer 204, while a negative value of the distance may indicate that the semiconductor chip 202 is recessed in the encapsulation layer by this distance.

The encapsulation layer 204 may encapsulate (e.g. partially or fully encapsulate) the semiconductor chip 202. For example, the encapsulation layer 204 may be formed at or over the first surface 202a (e.g. a backside or top surface) and at least one sidewall 202c of the semiconductor chip 202. For example, the encapsulation layer 204 may be formed at or over the first surface 202a (e.g. a backside or top surface) and all four sidewalls 202c of the semiconductor chip 202. Accordingly, the encapsulation layer 204 may enclose the semiconductor chip 202 from the first surface 202a (e.g. a backside or top surface) and from at least one sidewall 202c (e.g. from all four sidewalls 202c).

The encapsulation layer 204 may include, or may consist of, a molding material. In other words, the encapsulation layer 204 may include, or may consist of, a material that may be molded (e.g. by means of a molding process). The encapsulation layer 204 may include, or may consist of, a material different from the semiconductor chip 202.

The encapsulation layer 204 may include, or may consist of, at least one material selected from a group of materials, the group consisting of: a plastic material, a ceramic material, silicon and a glass material, although other materials may be possible as well. By way of an example, the encapsulation layer 204 may include, or may consist of, a plastic material e.g. a thermosetting polymer, e.g. an epoxy resin or a filled epoxy resin, e.g. a mold compound, e.g. a thermosetting mold compound. By way of another example, the encapsulation layer 204 may include, or may consist of, a plastic material (e.g. a thermoplastic, such as, for example, a high purity fluoropolymer).

The encapsulation layer 204 may have a receiving region 204-R, which may be configured to receive a device (e.g. an electronic device). The receiving region 204-R of the encapsulation layer 204 may include a cavity 204-RC. The cavity 204-RC of the receiving region 204-R may, for example, be disposed at a second side 204b (e.g. a backside or top surface) of the encapsulation layer 204 opposite the first side 204a (e.g. a frontside or a bottom surface), as shown in FIG. 2.

As described above, the semiconductor chip 202 may be disposed at the first side 204a (e.g. a frontside or a bottom surface) of the encapsulation layer 204. Consequently, the cavity 204-RC, which may be disposed at the second side 204b (e.g. a backside or top surface) of the encapsulation layer 204, may, for example, be disposed over (or at least partially over) the semiconductor chip 202, as shown in FIG. 2. However, the cavity 204-RC may also be disposed laterally adjacent to the semiconductor chip 202 (see, for example, description below in relation to FIG. 7).

The chip arrangement 200 may include an electronic device 206, which may be disposed in the receiving region 204-R. For example, the electronic device 206 may be disposed in the cavity 204-RC of the receiving region 204-R of the encapsulation layer 204, as shown in FIG. 2.

The electronic device 206 may, for example, include, or may be, an oscillator (e.g. a mechanical oscillator). The electronic device 206 may, for example, include, or may be, a micro-electromechanical system chip (MEMS chip). The electronic device 206 may, for example, include, or may be, a sensor. The electronic device 206 may, for example, include, or may be, a semiconductor chip (or die). The electronic device 206 may, for example, include, or may be, a device that may be sensitive to stress (e.g. mechanical stress) and/or that may require free headroom (e.g. a gap) in order to function properly. The electronic device 206 may, for example, include, or may be, a passive electrical component (e.g. a resistor and/or a capacitor and/or an inductor).

The electronic device 206 disposed in the cavity 204-RC of the receiving region 204-R may be spaced apart from at least one sidewall 204-RCW of the cavity 204-RC. In other words, there may be a gap (e.g. an air gap) between at least one sidewall 204-RCW of the cavity 204-RC and the electronic device 206. For example, as shown in FIG. 2, the electronic device 206 may be spaced apart from more than one sidewall 204-RCW of the cavity 204-RC, e.g. from all sidewalls of the cavity 204-RC. Spacing the electronic device 206 apart from at least one sidewall 204-RCW of the cavity 204-RC may decouple (e.g. mechanically decouple) the electronic device 206 from the encapsulation layer 204. In other words, a provision of a space (e.g. an air gap) between the electronic device 206 and the encapsulation layer 204 may cushion (e.g. shield or protect) the electronic device 206 from stresses (e.g. mechanical stresses) that may occur in the encapsulation layer 204.

The electronic device 206 disposed in the cavity 204-RC of the receiving region 204-R may be further decoupled from the encapsulation layer 204. For example, the electronic device 206 may be attached to a wall of the cavity 204-RC by means of a mechanically decoupling material 216. In other words, a mechanically decoupling material 216 interposed between the electronic device 206 and a wall of the cavity 204-RC may cushion the electronic device 206 from mechanical stresses that may occur in the encapsulation layer 204. As used herein, a wall of the cavity 204-RC may include a surface 204-RCS (e.g. a floor and/or a ceiling) of the cavity 204-RC and/or at least one sidewall 204-RCW of the cavity 204-RC. For example, as shown in FIG. 2, the electronic device 206 may be attached to the surface 204-RCS (e.g. a floor) of the cavity 204-RC via the mechanically decoupling material 216.

The mechanically decoupling material 216 may include, or may be, an adhesive (e.g. a soft adhesive). The mechanically decoupling material 216 (e.g. adhesive, for example, soft adhesive) may be formed at (e.g. applied to) the wall (e.g. surface 204-RCS) of the cavity 204-RC by at least one of the following processes: laminating, printing, and dispensing, although other processes may be possible as well.

Alternatively, or in addition to this, the mechanically decoupling material 216 (e.g. adhesive, for example, soft adhesive) may, for example, be formed at (e.g. applied to or deposited on) a side 206b of the electronic device 206. The electronic device 206 having the mechanically decoupling material 216 may be subsequently disposed in the cavity 206-RC.

The chip arrangement 200 may include a lid 218, which may be attached to the encapsulation layer 204 (e.g. via an adhesive 220, for example, a soft adhesive). A material of the adhesive 220 may be the same as the mechanically decoupling material 216, or may be different. The lid 218 may close (e.g. seal) the cavity 204-RC of the receiving region 204-R and may, for example, seal the electronic device 206 disposed in the cavity 204-RC. The lid 218 may, for example, seal the electronic device 206 (e.g. protect the electronic device 206) against water, moisture, contaminants or other elements that may be present in the ambient atmosphere which may be detrimental to the electronic device 206. By way of another example, the lid 218 may, for example, provide a hermetic seal (namely, an air-tight seal) for the electronic device 206. By way of yet another example, the lid 218 may protect the electronic device 206 from mechanical damage, which may occur, for example, during electrical test of the chip arrangement 200 and/or at board assembly of the chip arrangement 200 and/or during subsequent process flow steps that may occur whilst manufacturing the chip arrangement 200.

As described above, the electronic device 206 may be a device (e.g. a mechanical oscillator) that may need free headroom (e.g. a gap) to function properly (e.g. to allow mechanical parts to move freely). For example, the electronic device 206 may require free headroom (e.g. a gap) at (e.g. above) an active area formed at an active side 206a of the electronic device 206. Accordingly, an active side 206a of the electronic device 206 may face the lid 218, and there may be a gap G disposed between the electronic device 206 (e.g. the active side 206a of the electronic device 206) and the lid 218. In other words, the cavity 204-RC may be closed (e.g. sealed) by the lid 218 such that, for example, there may be a gap G between the lid 218 and the electronic device 206 (e.g. the active side 206a of the electronic device 206). Provision of the gap G (e.g. an air gap) between the electronic device 206 and the lid 218 may provide mechanical decoupling to the electronic device 206. In other words, the gap G may act as a cushion against mechanical stresses that may occur in the lid 218.

As described above, there may be a gap (e.g. an air gap) between at least one sidewall 204-RCW of the cavity 204-RC and the electronic device 206. For example, the electronic device 206 may be spaced apart from all sidewalls of the cavity 204-RC. In such an example, there may be a gap (e.g. an air gap) at all four sidewalls of the electronic device 206. Furthermore, there may be a gap G (e.g. air gap) between the electronic device 206 and the lid 218. In such an example, there may be a gap (e.g. an air gap) at the active side 206a of the electronic device. The gap (e.g. air gap) at the active side 206a and at all four sidewalls of the electronic device 206 may provide mechanical decoupling at five sides of the electronic device 206. Furthermore, the mechanically decoupling material 216 interposed between the electronic device 206 and a wall of the cavity 204-RC may provide mechanical decoupling at a sixth side (e.g. side 206b) of the electronic device 206.

The lid 218 may include, or may consist of, at least one material selected from a group of materials, the group consisting of: a glass material, a ceramic material, a polymer material, and a metal or metal alloy, although other materials may be possible as well. For example, the lid 218 may include, or may consist of, a glass material, a ceramic material and/or a metal or metal alloy, which may, for example, enable the lid 218 to act as a hermetic seal (i.e. an airtight seal) for the electronic device 206.

In addition to, or as an alternative to, the sealing provided by the lid 218, at least one wall of the cavity 204-RC may be coated at least partially with a sealing layer or sealing material. For example, the surface 204-RCS (e.g. a floor) and/or at least one sidewall 204-RCW of the cavity 204-RC may be coated (e.g. partially or fully coated) with a sealing material (sealing material not shown in FIG. 2). The sealing material may, for example, include, or may be, an impermeable or dense material (e.g. a water proof material) that may protect the electronic device 206 against water and moisture. The sealing material may provide better sealing of the cavity 204-RC and encapsulation of the electronic device 206, for example, in the cavity 204-RC.

The sealing material (or sealing layer) may include, or may consist of, at least one material selected from a group of materials, the group consisting of: a ceramic material, a polymer material, a metal or metal alloy, and a liquid crystal polymer material, although other materials may be possible as well. For example, the sealing layer may include, or may consist of, a metal (e.g. copper). In such an example, electrical short circuits may need to be avoided in the sealing layer. Accordingly, the sealing layer may, for example, include, or may be, a RDL (e.g. a single layer RDL or a multi-layer RDL) disposed fully or partially over or within an insulating layer. By way of another example, the sealing layer may include, or may consist of, a polymer (e.g. parylene, for example a parylene layer having a thickness of about 1 μm).

The chip arrangement 200 may include a second RDL 210-2a, 210-2b. The second RDL 210-2a, 210-2b may, for example, be a backside RDL of the chip arrangement 200.

The second RDL 210-2a, 210-2b (e.g. backside RDL) may be at least partially disposed in the cavity 204-RC. For example, as shown in FIG. 2, a first part 210-2a of the second RDL 210-2a, 210-2b may be disposed in the cavity 204-RC, and a second part 210-2b of the second RDL 210-2a, 210-2b may be disposed over the second side 204b (e.g. a backside or top surface) of the encapsulation layer 204 which may be outside the cavity 204-RC. In other words, the second RDL 210-2a, 210-2b shown in the chip arrangement 200 may be partially disposed in the cavity 204-RC.

The second RDL 210-2a, 210-2b may include, or may consist of, at least one electrically conductive material. The at least one electrically conductive material may be selected from a group of electrically conductive materials, the group consisting of: a metal or a metal alloy, although other electrically conductive materials may be possible as well. For example, the second RDL 210-2 may include, or may consist of, copper, aluminum, titanium, tungsten, nickel, palladium, gold, or a metal alloy including one or more of the following metals: copper, aluminum, titanium, tungsten, nickel, palladium, and gold.

The second RDL 210-2a, 210-2b may be formed by, for example, at least one of the following processes: sputtering, resist deposition, resist structuring, electroplating, resist stripping, etching, electro-less plating, dispensing, and printing, although other processes may be possible as well.

The second RDL 210-2a, 210-2b may be coupled (e.g. electrically coupled) to the electronic device 206 (e.g. to the active side 206a of the electronic device 206), for example, via at least one bonding wire 221, which may be disposed in the cavity 204-RC.

The at least one bonding wire 221 may include, or may consist of, at least one electrically conductive material, e.g. a metal and/or metal alloy. The at least one electrically conductive material may be selected from a group of electrically conductive materials, the group consisting of: aluminum, copper, and gold, although other electrically conductive materials may be possible as well.

Connecting (e.g. electrically connecting) the electronic device 206 (e.g. the active side 206a of the electronic device 206) to the second RDL 210-2a, 210-2b via the at least one bonding wire 221 may, for example, provide good mechanical decoupling of the electronic device 206 from its surroundings (e.g. from the encapsulation layer 204 and/or the second RDL 210-2a, 210-2b).

As described above, the adhesive 220 (e.g. soft adhesive) may attach the encapsulation layer 204 to the lid 218 (e.g. including, or consisting of, a metal or metal alloy). The adhesive 220 may, for example, also act as insulation (e.g. electrical insulation). For example, the adhesive 220 shown in FIG. 2 may insulate (e.g. electrically insulate) the lid 218 (e.g. including, or consisting of, a metal or metal alloy) from the second part 210-2b of the second RDL 210-2a, 210-2b outside the cavity 204-RC. Accordingly, the adhesive 220 may be, for example, a non-conductive adhesive.

The chip arrangement 200 may include at least one through-via 222 disposed in the encapsulation layer 204. In the following, it is assumed that the encapsulation layer 204 includes or is made of a molding material (mold compound). Therefore, the at least one through-via 222 disposed in the encapsulation layer 204 may also be referred to as a through-mold via (TMV) 222 in the following (similarly, through-vias 322, 522 shown in FIGS. 3 and 5 may also be referred to as TMVs). However, as will be readily understood and is described above, the encapsulation layer 204 may include or may be made of other materials.

The at least one TMV 222 may include, or may consist of, at least one electrically conductive material, e.g. a metal and/or metal alloy. The at least one electrically conductive material may be selected from a group of electrically conductive materials, the group consisting of: aluminum, copper, gold, titanium, tungsten, palladium, silver, and a solder alloy (e.g. a Sn—Ag—Cu solder alloy), although other electrically conductive materials may be possible as well. The at least one electrically conductive material may include, or may be, a conductive paste or conductive adhesive. For example, the conductive paste or conductive adhesive may include, or may consist of, at least one polymer that may be filled with electrically conductive particles, e.g. metal particles, e.g. silver particles.

The at least one TMV 222 may be formed by, for example, at least one of the following processes: drilling (e.g. laser and/or mechanical drilling) and etching (e.g. dry and/or wet etching). The at least one TMV 222 may be filled with at least one of the above-identified electrically conductive materials by, for example, a plating process (e.g. an electroplating and/or electroless plating process), a printing process, a dispensing process, and a ball drop and reflow process, although other processes may be possible as well. For example, a printing and/or dispensing process may be performed in case the at least one TMV 222 includes, or consists of, a conductive paste or conductive adhesive. By way of another example, a ball drop and reflow process may be performed in case the at least one TMV 222 includes, or consists of, a solder alloy configured as preformed solder balls.

The at least one TMV 222 disposed in the encapsulation layer 204 may extend from the first side 204a (e.g. frontside or a bottom surface) to the second side 204b (e.g. backside or top surface) of the encapsulation layer 204, as shown in FIG. 2. The at least one TMV 222 may be coupled (e.g. electrically coupled) to the second RDL 210-2a, 210-2b (e.g. backside RDL). For example, the at least one TMV 222 shown in FIG. 2 may extend from the first side 204a (e.g. frontside or a bottom surface) of the encapsulation layer 204 to the second part 210-2b of the second RDL 210-2a, 210-2b (e.g. backside RDL), which may be disposed over the second side 204b (e.g. a backside or top surface) of the encapsulation layer 204 which may be outside the cavity 204-RC.

The first RDL 210-1 (e.g. frontside RDL) and the second RDL 210-2a, 210-2b (e.g. backside RDL) may be connected (e.g. electrically connected) via the at least one TMV 222. Consequently, the electronic device 206 (e.g. the active side 206a of the electronic device 206) may be coupled (e.g. electrically coupled) to the semiconductor chip 202, and to the plurality of solder balls 212 via, for example, the at least one bonding wire 221, the second RDL 210-2a, 210-2b (e.g. backside RDL), the at least one TMV 222, and the first RDL 210-1 (e.g. frontside RDL).

An effect provided by the chip arrangement 200 may be an ability to package and/or integrate a device (e.g. the electronic device 206) that may be sensitive to thermo-mechanical stresses and/or that may require free headroom (e.g. a gap) in a chip package (e.g. an eWLB package).

An effect provided by the chip arrangement 200 may be an ability to package and/or integrate a device (e.g. the electronic device 206) that may be sensitive to thermo-mechanical stresses and/or that may require free headroom (e.g. a gap) with at least one other device (e.g. the semiconductor chip 202) in a chip package (e.g. an eWLB package) to realize, for example, a SiP (system-in-package).

An effect provided by the chip arrangement 200 may be substantial reduction or elimination of mechanical stresses in a chip package (e.g. an eWLB package) that may be exerted against a device (e.g. the electronic device 206) that may be sensitive to thermo-mechanical stresses and/or that may require free headroom (e.g. a gap).

An effect provided by the chip arrangement 200 may be protection and/or sealing of a device (e.g. the electronic device 206) that may be sensitive to thermo-mechanical stresses and/or that may require free headroom (e.g. a gap) against water, moisture, contaminants or other elements that may be present in the ambient atmosphere which may be detrimental to the device.

FIG. 3 shows a cross-sectional view of a chip arrangement 300 including the second RDL 210-2 which may be fully disposed in the cavity 204-RC.

Reference signs in FIG. 3 that are the same as in FIG. 2 denote the same or similar elements as in FIG. 2. Thus, those elements will not be described in detail again here; reference is made to the description above. The various effects described above in relation to the chip arrangement 200 shown in FIG. 2 may be analogously valid for the chip arrangement 300 shown in FIG. 3. Differences between FIG. 3 and FIG. 2 are described below.

As shown in FIG. 3, the second RDL 210-2 may be disposed (e.g. fully disposed) in the cavity 204-RC. In other words, the second RDL 210-2 may not have a part that may be disposed outside the cavity 204-RC.

At least one TMV 322 shown in FIG. 3 may be coupled (e.g. electrically coupled) to the second RDL 210-2 (e.g. backside RDL). Since the second RDL 210-2 may be disposed (e.g. fully disposed) in the cavity 204-RC, the at least one TMV 322 of the chip arrangement 300 may extend from the first side 204a (e.g. a frontside or a bottom surface) of the encapsulation layer 204 to the cavity 204-RC. For example, the at least one TMV 322 shown in FIG. 3 may extend from the first side 204a (e.g. a frontside or a bottom surface) of the encapsulation layer 204 to the second RDL 210-2 (e.g. backside RDL), which may be disposed (e.g. fully disposed) in the cavity 204-RC.

The at least one TMV 322 may include, or may consist of, at least one electrically conductive material, e.g. a metal or metal alloy. The at least one electrically conductive material may be selected from a group of electrically conductive materials, the group consisting of: aluminum, copper, gold, titanium, tungsten, palladium, silver, and a solder alloy (e.g. a Sn—Ag—Cu solder alloy), although other electrically conductive materials may be possible as well. The at least one electrically conductive material may include, or may be, a conductive paste or conductive adhesive. For example, the conductive paste or conductive adhesive may include, or may consist of, at least one polymer filled with electrically conductive particles, e.g. metal particles, e.g. silver particles.

The at least one TMV 322 may be formed by, for example, at least one of the following processes: drilling (e.g. laser and/or mechanical drilling) and etching (e.g. dry and/or wet etching). The at least one TMV 322 may be filled with at least one of the above-identified electrically conductive materials by, for example, a plating process (e.g. an electroplating and/or electroless plating process), a printing process, a dispensing process, and a ball drop and reflow process, although other processes may be possible as well. For example, a printing and/or dispensing process may be performed in case the at least one TMV 322 includes, or consists of, a conductive paste or conductive adhesive. By way of another example, a ball drop and reflow process may be performed in case the at least one TMV 322 includes, or consists of, a solder alloy configured as preformed solder balls.

As a consequence of the second RDL 210-2 being disposed (e.g. fully disposed) in the cavity 204-RC, the at least one TMV 322 of the chip arrangement 300 may have a shorter height H compared to the at least one TMV 222 of the chip arrangement 200. As used herein, a height H of the at least one TMV 322 or TMV 222 may be measured in a direction perpendicular to the first side 204a (e.g. a frontside or a bottom surface) of the encapsulation layer 204.

As a consequence of the second RDL 210-2 being disposed (e.g. fully disposed) in the cavity 204-RC, the at least one TMV 322 of the chip arrangement 300 may have a smaller aspect ratio than the at least one TMV 222 of the chip arrangement 200. An aspect ratio of a TMV may be calculated as a ratio of a height H of the TMV to a width W of the TMV. In other words, the aspect ratio of the TMV may be calculated as H:W.

A smaller aspect ratio (H:W) and/or shorter height H of the at least one TMV 322 of the chip arrangement 300 may provide a more reliable connection (e.g. electrical connection) between the first RDL 210-1 (e.g. frontside RDL) and the second RDL 210-2 (e.g. backside RDL). Furthermore, the at least one TMV 322 of the chip arrangement 300 may be easier to manufacture (e.g. by means of electroplating) compared to the at least one TMV 222 of the chip arrangement 200. For example, filling the at least one TMV 322 of the chip arrangement 300 (e.g. with a metal or metal alloy, for example, copper) may be easier compared to the at least one TMV 222 of the chip arrangement 200.

Consequently, the electronic device 206 (e.g. the active side 206a of the electronic device 206) shown in FIG. 3 may be coupled (e.g. electrically coupled) to the semiconductor chip 202, and to the plurality of solder balls 212 via, for example, the at least one bonding wire 221, the second RDL 210-2 (e.g. backside RDL), the at least one TMV 322 (e.g. having shorter height H and/or smaller aspect ratio H:W), and the first RDL 210-1 (e.g. frontside RDL).

As described above in relation to FIG. 2, the adhesive 220 (e.g. soft adhesive) may, for example, insulate (e.g. electrically insulate) the second part 210-2b of the second RDL 210-2 outside the cavity 204-RC from the lid 218 (e.g. including, or consisting of, a metal or metal alloy). In the chip arrangement 300 shown in FIG. 3, the second RDL 210-2 may be fully disposed in the cavity 204-RC. Accordingly, the adhesive 220 may, for example, not be needed for insulation (e.g. electrical insulation) purposes. In such an example, the lid 218 may be attached to the encapsulation layer 204 and seal the cavity 204-RC without use of the adhesive 220. Alternatively, the adhesive 220 may be provided to attach the lid 218, similarly as in the chip arrangement 200 of FIG. 2.

FIG. 4 shows a cross-sectional view of a chip arrangement 400 including at least one flip chip interconnect 421 disposed in the cavity 204-RC and coupling the electronic device 206 to the second RDL 210-2a, 210-2b.

Reference signs in FIG. 4 that are the same as in FIG. 2 denote the same or similar elements as in FIG. 2. Thus, those elements will not be described in detail again here; reference is made to the description above. The various effects described above in relation to the chip arrangement 200 shown in FIG. 2 may be analogously valid for the chip arrangement 400 shown in FIG. 4. Differences between FIG. 4 and FIG. 2 are described below.

In contrast to the chip arrangement 200 shown in FIG. 2, the chip arrangement 400 shown in FIG. 4 shows that the second RDL 210-2a, 210-2b may be coupled (e.g. electrically coupled) to the electronic device 206 (e.g. to the active side 206a of the electronic device 206) via, for example, at least one flip chip interconnect 421, which may be disposed in the cavity 204-RC. In other words, the at least one bonding wire 221 of the chip arrangement 200 may be replaced by the at least one flip chip interconnect 421.

The at least one flip chip interconnect 421 may include, or may consist of, at least one electrically conductive material selected from a group of electrically conductive materials, the group consisting of: a metal or metal alloy. For example, the at least one flip chip interconnect 421 may consist of a solder material (e.g. an alloy of tin, silver, and copper). By way of another example, the at least one flip chip interconnect 421 may include a pillar (e.g. a metal or metal alloy pillar, e.g. a copper pillar) that may be capped, e.g. with solder. By way of yet another example, the at least one flip chip interconnect 421 may include a stud bump (e.g. a metal stud bump, e.g. a gold stud bump).

The at least one flip chip interconnect 421 may, for example, be formed at the side 206b of the electronic device 206 opposite the active side 206a. In an example where the at least one flip chip interconnect 421 includes or is a stud bump (e.g. a metal stud bump, e.g. a gold stud bump), the flip chip connection may be achieved by means of at least one of an NCA (non-conductive adhesive), an ICA (isotropic-conductive adhesive) and an ACA (anisotropic conductive adhesive). The electronic device 206 having the at least one flip chip interconnect 421 may subsequently be disposed in the cavity 204-RC (e.g. disposed over the first part 210-2a of the second RDL 210-2a, 210-2b disposed in the cavity 204-RC) such that the active area 206a of the electronic device 206 faces the lid 218. For example, the at least one flip chip interconnect 421 may be attached to the first part 210-2a of the second RDL 210-2a, 210-2b by means of a soldering process. In such an example, a flux or a solder paste may be applied to the first part 210-2a of the second RDL 210-2a, 210-2b. By way of another example, the flip chip connection may be made by means of adhesive bonding with an NCA, ICA, or ACA.

Alternatively, the at least one flip chip interconnect 421 may, for example, be disposed in the cavity 204-RC (e.g. disposed over the first part 210-2a of the second RDL 210-2 disposed in the cavity 204-RC) prior to placing the electronic device 206 in the cavity 204-RC. The electronic device 206 may subsequently be disposed in (e.g. placed in) the cavity 204-RC and over the at least one flip chip interconnect 421 such that the active area 206a of the electronic device 206 faces the lid 218.

The at least one flip chip interconnect 421 may be connected (e.g. electrically connected) to the electronic device 206 via at least one flip chip interface 423 (e.g. at least one pad) formed at the side 206b of the electronic device 206 opposite the active side 206a. At least one through-via 425 (e.g. a through-silicon via (TSV) and/or a TMV) may connect (e.g. electrically connect) the active side 206a of the electronic device 206 to the at least one flip chip interface 423.

Consequently, the electronic device 206 (e.g. the active side 206a of the electronic device 206) shown in FIG. 4 may be coupled (e.g. electrically coupled) to the semiconductor chip 202, and to the plurality of solder balls 212 via, for example, the at least one through-via 425, the at least one flip chip interconnect 421, the second RDL 210-2a, 210-2b (e.g. backside RDL), the at least one TMV 222, and the first RDL 210-1 (e.g. frontside RDL).

As shown in FIG. 4, the chip arrangement 400 may include an insulating layer 427 disposed in the cavity 204-RC, which may insulate (e.g. electrically insulate) the connection formed between the at least one flip chip interconnect 421 and the second RDL 210-2a, 210-2b.

FIG. 5 shows a cross-sectional view of a chip arrangement 500 including at least one TMV 522 disposed in the encapsulation layer 204 between the semiconductor chip 202 and the cavity 204-RC.

Reference signs in FIG. 5 that are the same as in FIG. 4 denote the same or similar elements as in FIG. 4. Thus, those elements will not be described in detail again here; reference is made to the description above. The various effects described above in relation to the chip arrangement 400 shown in FIG. 4 may be analogously valid for the chip arrangement 500 shown in FIG. 5. Differences between FIG. 5 and FIG. 4 are described below.

As shown in FIG. 5, the second RDL 210-2 may be disposed (e.g. fully disposed) in the cavity 204-RC. In other words, the second RDL 210-2 may not have a part that may be disposed outside the cavity 204-RC.

As described above, the second RDL 210-2 may be coupled (e.g. electrically coupled) to the electronic device 206 via, for example, the at least one flip chip interconnect 421. In addition, the second RDL 210-2 may be coupled (e.g. electrically coupled) to at least one TMV 522, which may be disposed in the encapsulation layer 204. As shown in FIG. 5, the at least one TMV 522 may be disposed in the encapsulation layer 204 between the semiconductor chip 202 and the cavity 204-RC.

The at least one TMV 522 may include, or may consist of, at least one electrically conductive material, e.g. a metal and/or metal alloy. The at least one electrically conductive material may be selected from a group of electrically conductive materials, the group consisting of: aluminum, copper, gold, titanium, tungsten, palladium, silver, and a solder alloy (e.g. a Sn—Ag—Cu solder alloy), although other electrically conductive materials may be possible as well. The at least one electrically conductive material may include, or may be, a conductive paste or conductive adhesive. For example, the conductive paste or conductive adhesive may include, or may consist of, at least one polymer filled with electrically conductive particles, e.g. metal particles, e.g. silver particles.

The at least one TMV 522 may be formed by, for example, at least one of the following processes: drilling (e.g. laser and/or mechanical drilling) and etching (e.g. dry and/or wet etching). The at least one TMV 522 may be filled with at least one of the above-identified electrically conductive materials by, for example, a plating process (e.g. an electroplating and/or electroless plating process, a printing process, a dispensing process, and a ball drop and reflow process, although other processes may be possible as well. For example, a printing and/or dispensing process may be performed in case the at least one TMV 322 includes, or consists of, a conductive paste or conductive adhesive. By way of another example, a ball drop and reflow process may be performed in case the at least one TMV 322 includes, or consists of, a solder alloy configured as preformed solder balls.

The at least one TMV 522 may, for example, provide a connection (e.g. an electrical connection) between the electronic device 206 and the semiconductor chip 202. As described above, at least one pad 202e may be formed (e.g. additionally formed) at the first surface 202a (e.g. backside or top surface) of the semiconductor chip 202. Therefore, the at least one TMV 522 may be coupled (e.g. electrically coupled) to the semiconductor chip 202 via the at least one pad 202e formed at the first surface 202a (e.g. backside or top surface) of the semiconductor chip 202.

The semiconductor chip 202 may include at least one through-via 527 formed within the semiconductor chip 202, as shown in FIG. 5. In the following, it is assumed that the semiconductor chip 202 is a silicon chip. Therefore, the at least one through-via 527 may also be referred to as a through-silicon via (TSV) 527 in the following. However, as will be readily understood and is described above, the semiconductor chip 202 may include or may be made of other materials.

The at least one TSV 527 may include, or may consist of, at least one electrically conductive material, e.g. a metal and/or metal alloys. The at least one electrically conductive material may be selected from a group of electrically conductive materials, the group consisting of: aluminum, copper, gold, titanium, and tungsten, although other electrically conductive materials may be possible as well.

The at least one TSV 527 may be formed by, for example, at least one of the following processes: drilling (e.g. laser and/or mechanical drilling) and etching (e.g. dry and/or wet etching). The at least one TSV 527 may be filled with at least one of the above-identified electrically conductive materials by, for example, a plating process (e.g. an electroplating and/or electroless plating process).

The at least one TSV 527 may connect (e.g. electrically connect) the at least one pad 202e formed at the first surface 202a (e.g. backside or top surface) of the semiconductor chip 202 and the at least one pad 202d formed at the second surface 202b (e.g. frontside or bottom surface) of the semiconductor chip 202.

Consequently, the electronic device 206 (e.g. the active side 206a of the electronic device 206) may be coupled (e.g. electrically coupled) to the semiconductor chip 202, and to the plurality of solder balls 212 via, for example, the at least one through-via 425, the at least one flip chip interconnect 421, the second RDL 210-2 (e.g. backside RDL), the at least one TMV 522, the at least one TSV 527, and the first RDL 210-1 (e.g. frontside RDL).

FIG. 6 shows a cross-sectional view of a chip arrangement 600 including at least one flip chip interconnect 421 which may be in contact with the first surface 202a (e.g. backside or top surface) of the semiconductor chip 202.

Reference signs in FIG. 6 that are the same as in FIG. 5 denote the same or similar elements as in FIG. 5. Thus, those elements will not be described in detail again here; reference is made to the description above. The various effects described above in relation to the chip arrangement 500 shown in FIG. 5 may be analogously valid for the chip arrangement 600 shown in FIG. 6. Differences between FIG. 6 and FIG. 5 are described below.

The chip arrangement 600 may include a connection (e.g. an electrical connection), for example, a direct connection, between the at least one flip chip interconnect 421 and the semiconductor chip 202. For example, the at least one flip chip interconnect 421 may be in contact with the first surface 202a (e.g. backside or top surface) of the semiconductor chip 202. For example, the at least one flip chip interconnect 421 may be in contact with the at least one pad 202e formed at the first surface 202a (e.g. backside or top surface) of the semiconductor chip 202. Accordingly, the chip arrangement 600 shown in FIG. 6 may not require the second RDL 210-2 and/or the at least one TMV 522 to redistribute and/or re-map electrical connections from the at least one flip chip interconnect 421 to the semiconductor chip 202. One or more openings (e.g. small openings) formed in the encapsulation layer 204 (e.g. by means of drilling, for example, laser drilling) may allow the at least one flip chip interconnect 421 to be in contact with, for example, the at least one pad 202e formed at the first surface 202a (e.g. backside or top surface) of the semiconductor chip 202. For example, one or more openings may be formed in a wall (e.g. the surface 204-RCS (e.g. a floor)) of the cavity 204-RC, and through the one or more openings the at least one flip chip interconnect 421 may contact the at least one pad 202e formed at the first surface 202a (e.g. backside or top surface) of the semiconductor chip 202. In an example where the one or more openings have a high aspect ratio, e.g. an aspect ratio of at least about 0.3, e.g. an aspect ratio of at least about 0.5, e.g. an aspect ratio of at least about 0.7, the one or more openings may be filled with solder, e.g. in a ball drop and reflow process. By way of another example, the one or more openings having a high aspect ratio may be filled with solder paste, e.g. in a paste dispensing and reflow process.

Consequently, the electronic device 206 (e.g. the active side 206a of the electronic device 206) may be coupled (e.g. electrically coupled) to the semiconductor chip 202, and to the plurality of solder balls 212 via, for example, the at least one through-via 425, the at least one flip chip interconnect 421, the at least one TSV 527, and the first RDL 210-1 (e.g. frontside RDL).

FIG. 7 shows a cross-sectional view of a chip arrangement 700 including the semiconductor chip 202 and the cavity 204-RC disposed at a same side of the encapsulation layer 204.

Reference signs in FIG. 7 that are the same as in FIG. 2 denote the same or similar elements as in FIG. 2. Thus, those elements will not be described in detail again here; reference is made to the description above. The various effects described above in relation to the chip arrangement 200 shown in FIG. 2 may be analogously valid for the chip arrangement 700 shown in FIG. 7. Differences between FIG. 7 and FIG. 2 are described below.

As described above, the semiconductor chip 202 may be disposed at the first side 204a (e.g. a frontside or a bottom surface) of the encapsulation layer 204, and the encapsulation layer 204 may have a receiving region 204-R, which may include a cavity 204-RC.

In contrast to the chip arrangement 200 shown in FIG. 2, the cavity 204-RC of the receiving region 204-R of the chip arrangement 700 may, for example, be disposed at the first side 204a (e.g. a frontside or bottom surface) of the encapsulation layer 204. In other words, the semiconductor chip 202 and the cavity 204-RC may be disposed at the same side (e.g. the first side 204a, for example, a frontside or bottom surface) of the encapsulation layer 204. For example, the cavity 204-RC of the chip arrangement 700 may be disposed laterally adjacent to the semiconductor chip 202.

As described above, the first RDL 210-1a, 210-1b (e.g. frontside RDL) may, for example, be connected (e.g. electrically connected) to the semiconductor chip 202. As a consequence of the semiconductor chip 202 and the cavity 204-RC being disposed at the same side (e.g. a frontside) of the encapsulation layer 204, the first RDL 210-1a, 210-1b (e.g. frontside RDL) may, for example, be used to connect (e.g. electrically connect) the electronic device 206 to, for example, the semiconductor chip 202 and/or the plurality of solder balls 212. In other words, the second RDL 210-2 (e.g. backside RDL) and the at least one TMV 222 may not be needed to couple (e.g. electrically couple) the semiconductor chip 202 to the electronic device 206.

The first RDL 210-1a, 210-1b may be at least partially disposed in the cavity 204-RC, and may be electrically coupled to the electronic device 206. For example, as shown in FIG. 7, the first RDL 210-1a, 210-1b (e.g. frontside RDL) may include a first part 210-1a that may be disposed in the cavity 204-RC, and a second part 210-1b that may be disposed outside the cavity 204-RC. The first part 210-1a of the first RDL 210-1a, 210-1b (e.g. frontside RDL) may be coupled (e.g. electrically coupled) to the electronic device 206.

As shown in FIG. 7, the first RDL 210-1a, 210-1b (e.g. the first part 210-1a of the first RDL 210-1a, 210-1b) may be coupled (e.g. electrically coupled) to the electronic device 206 (e.g. to the active side 206a of the electronic device 206), for example, via the at least one bonding wire 221, which may be disposed in the cavity 204-RC.

Consequently, the electronic device 206 (e.g. the active side 206a of the electronic device 206) may be coupled (e.g. electrically coupled) to the semiconductor chip 202, and to the plurality of solder balls 212 via, for example, the at least one bonding wire 221 and the first RDL 210-1a, 210-1b (e.g. frontside RDL).

Alternatively, the first RDL 210-1a, 210-1b (e.g. the first part 210-1a of the first RDL 210-1a, 210-1b) may be coupled (e.g. electrically coupled) to the electronic device 206 (e.g. to the active side 206a of the electronic device 206), for example, via at least one flip chip interconnect (not shown in FIG. 7), which may be disposed in the cavity 204-RC. In such an example, the electronic device 206 (e.g. the active side 206a of the electronic device 206) may be coupled (e.g. electrically coupled) to the semiconductor chip 202, and to the plurality of solder balls 212 via, for example, the at least one flip chip interconnect and the first RDL 210-1a, 210-1b (e.g. frontside RDL). The cavity 204-RC may be open at the first side 204a (e.g. frontside or bottom surface) of the encapsulation layer 204. For example, the lid 218 may be omitted in the chip arrangement 700.

FIG. 8 shows a cross-sectional view of a chip arrangement 800 including the electronic device 206 disposed over the cavity 204-RC.

Reference signs in FIG. 8 that are the same as in FIG. 2 denote the same or similar elements as in FIG. 2. Thus, those elements will not be described in detail again here; reference is made to the description above. The various effects described above in relation to the chip arrangement 200 shown in FIG. 2 may be analogously valid for the chip arrangement 800 shown in FIG. 8. Differences between FIG. 8 and FIG. 2 are described below.

Instead of being disposed in the cavity 204-RC, the electronic device 206 may, for example, be disposed over the cavity 204-RC, and may be configured to seal the cavity 204-RC, as shown in FIG. 8. In other words, the electronic device may act as a lid for the cavity 204-RC.

The active side 206a of the electronic device 206 may, for example, face the cavity 204-RC. Therefore, the active side 206a of the electronic device 206 may be sealed against damage (e.g. by the cavity 204-RC). As described above, at least one wall of the cavity 204-RC may be coated at least partially with a sealing material (e.g. a metal or metal alloy) in order to encapsulate (e.g. protect) the electronic device 206. For example, the cavity 204-RC (e.g. a surface 204-RCS and at least one sidewall 204-RCW of the cavity 204-RC) may be coated with a sealing material 702 (e.g. a liquid crystal polymer (LCP) or parylene, or a metal or metal alloy, for example, copper or a copper alloy) for encapsulating (e.g. protecting) the electronic device 206. The sealing material 702 may provide better sealing of the cavity 204-RC and/or encapsulation of the electronic device 206 (e.g. active side 206a of the electronic device 206) in the cavity 204-RC.

The electronic device 206 disposed over the cavity 204-RC may be attached to the encapsulation layer 204, for example, along a perimeter of the cavity 204-RC.

The electronic device 206 may include at least one bump 705 formed at a surface (e.g. the active side 206a) of the electronic device 206. The at least one bump 705 may, for example, be connected (e.g. electrically connected) to circuitry that may be formed at the active side 206a of the electronic device 206. The at least one bump 705 may be coupled to the second RDL 210-2. The at least one bump 705 may be part of a flip chip interconnection between the electronic device 206 and the second RDL 210-2. The flip chip interconnection may further include an adhesive 703. The adhesive 703 may laterally surround the at least one bump 705.

The adhesive 703 may be an ACA (anisotropic conductive adhesive). In this case, a part of the adhesive 703 may be disposed between the at least one bump 705 and the second RDL 210-2, as shown in FIG. 8. The part of the adhesive 703 that is disposed between the at least one bump 705 and the second RDL 210-2 may have been compressed by the at least one bump 705 upon placement of the electronic device 206 over the cavity 204-RC, wherein the compression or thermocompression causes the part of the adhesive 703 disposed between the at least one bump 705 and the second RDL 210-2 to make electrical contact between the at least one bump 705 and the second RDL 210-2.

In another example, the adhesive 703 may be an NCA (non-conducting adhesive). In this case, the at least one bump 705 may be in contact, e.g. direct physical contact, with the second RDL 210-2 with no material of the adhesive 703 disposed between the at least one bump 705 and the second RDL 210-2 (not shown in FIG. 8).

For example, the at least one bump 705 may be a solder bump that may have been attached to the second RDL 210-2 by means of soldering, and a gap between the electronic device 206 and the encapsulation layer 204 along the perimeter of the cavity 204-RC may have been underfilled with the adhesive 703, for example by means of dispensing.

A quantity (e.g. a volume) of the adhesive 703 dispensed along the perimeter of the cavity 204-RC may be small enough so as to avoid that the adhesive 703 is disposed in the cavity 204-RC or fills the cavity 204-RC.

The chip arrangement 800 may include an insulating layer 720 formed over at least a part of the second RDL 210-2 and over at least a part of the second side 204b of the encapsulation layer 204. The insulating layer 720 may, for example, insulate (e.g. electrically insulate) the second RDL 210-2 and/or the at least one TMV 222.

FIG. 9 shows a plan view 900 of an example of the chip arrangement of FIG. 8, including the encapsulation layer 204, the adhesive 703, and the cavity 204-RC coated with the sealing layer 702 prior to disposing the electronic device 206 over the cavity 204-RC.

According to the example shown in FIG. 8, the adhesive 703 is an ACA (anisotropic conductive adhesive).

For example, the surface 204-RCS (e.g. a floor) of the cavity 204-RC and/or at least one sidewall 204-RCW of the cavity 204-RC may be coated with the sealing layer 702 prior to disposing the electronic device 206 over the cavity 204-RC.

The adhesive 703 may be formed (e.g. deposited and/or dispensed) along the perimeter of the cavity 204-RC, and over at least a part of the second RDL 210-2 (e.g. backside RDL), which may be disposed at the second side 204b of the encapsulation layer 204 and outside the cavity 204-RC, as shown in FIG. 8. The second RDL 210-2 may be coupled (e.g. electrically coupled) to the at least one TMV 222 shown in FIG. 8. Upon placement of the electronic device 206 over the cavity 204RC, a part of the adhesive 703 (anisotropic conducting adhesive) may be compressed or thermocompressed by the at least one bump 705 and the compressed part may electrically connect the at least one bump 705 to the second RDL 210-2 and thus to the at least one TMV 222.

Consequently, the electronic device 206 (e.g. the active side 206a of the electronic device 206) may be coupled (e.g. electrically coupled) to the semiconductor chip 202, and to the plurality of solder balls 212 via, for example, the at least one bump 705, the adhesive 703, the second RDL 210-2 (e.g. backside RDL), the at least one TMV 222, and the first RDL 210-1 (e.g. frontside RDL).

FIG. 10 shows a cross-sectional view of a chip arrangement 1000 including at least one bonding wire 1021 connecting the electronic device 206 and the at least one TMV 222.

Reference signs in FIG. 10 that are the same as in FIG. 8 denote the same or similar elements as in FIG. 8. Thus, those elements will not be described in detail again here; reference is made to the description above. The various effects described above in relation to the chip arrangement 800 shown in FIG. 8 may be analogously valid for the chip arrangement 1000 shown in FIG. 10. Differences between FIG. 10 and FIG. 8 are described below.

The at least one bump 705 of the chip arrangement 800 that may, for example, connect (e.g. electrically connect) the electronic device 206 to the at least one TMV 222 may be replaced by at least one bonding wire 1021, as shown in FIG. 10. Accordingly, the at least one bonding wire 1021 may be coupled (e.g. electrically coupled) to the electronic device 206 and to the at least one TMV 222. For example, the at least one bonding wire 1021 may be coupled (e.g. electrically coupled) to the electronic device 206 (e.g. to the active side 206a of the electronic device 206) by means of at least one through-via (e.g. TSV) 1025 formed within the electronic device 206. By way of another example, the at least one bonding wire 1021 may be coupled (e.g. electrically coupled) to the at least one TMV 222 by means of the second RDL 210-2 (e.g. backside RDL), which may be disposed at the second side 204b of the encapsulation layer 204 and outside the cavity 204-RC, as shown in FIG. 10.

Consequently, the electronic device 206 (e.g. the active side 206a of the electronic device 206) may be coupled (e.g. electrically coupled) to the semiconductor chip 202, and to the plurality of solder balls 212 via, for example, the at least one through-via (e.g. TSV) 1025, the at least one bonding wire 1021, the second RDL 210-2 (e.g. backside RDL), the at least one TMV 222, and the first RDL 210-1 (e.g. frontside RDL).

The above-described chip arrangements shown in FIG. 2 to FIG. 10 may, for example, be combined together to form other chip arrangements. For example, a chip arrangement may include a first electronic device disposed in the cavity 204-RC, and a second electronic device which may be disposed over the cavity 204-RC and configured to seal the cavity 204-RC (and consequently, the first electronic device disposed in the cavity 204-RC).

FIG. 11 shows a method 1100 for manufacturing a chip arrangement.

The method 1100 may, for example, be used to manufacture at least one of the chip arrangements shown in FIG. 2 to FIG. 10 and/or other chip arrangements that may be obtained by combining the features of the chip arrangements shown in FIG. 2 to FIG. 10.

The method 1100 for manufacturing the chip arrangement may include: providing a semiconductor chip (in 1102); forming an encapsulation layer to at least partially encapsulate the semiconductor chip (in 1104); forming a cavity in the encapsulation layer (in 1106); and disposing an electronic device in or over the cavity (in 1108).

As described above in relation to FIG. 2 to FIG. 10, the encapsulation layer may include, or may be, a molding material (namely, a material that may be molded). Accordingly, forming the encapsulation layer in 1104 may include a molding process.

The cavity may, for example, be formed during the forming of the encapsulation layer in 1104. For example, the cavity may be formed using a suitably shaped mold tool during the molding process, e.g. a mold tool with a suitably shaped protrusion. In other words, forming the cavity in the encapsulation layer may include forming the cavity during the molding process using a predetermined mold tool, wherein the mold tool may have a shape that is inverse to the shape of the cavity.

By way of another example, the cavity may be formed by removing material after forming the encapsulation layer. In other words, forming the cavity may include, or may be, a subtractive process. For example, forming the cavity in the encapsulation layer may include forming the cavity by removing material of the encapsulation layer after forming the encapsulation layer. Material of the encapsulation layer may, for example, be removed by means of at least one of the following process: ablation (e.g. laser ablation), milling, drilling (e.g. laser and/or mechanical drilling), etching (e.g. dry and/or wet etching), although other processes may be possible as well.

By way of yet another example, the cavity may be formed in the encapsulation layer by embedding a sacrificial material in the encapsulation layer when forming the encapsulation layer (e.g. during eWLB reconstitution), and subsequently removing the sacrificial material, for example, to open the cavity. For example, the sacrificial material may have a shape of the cavity. The sacrificial material may be removed by, for example, dissolving (e.g. selectively dissolving) the sacrificial material such that the encapsulation layer remains undamaged.

According to various examples described herein, a chip arrangement may be provided. The chip arrangement may include: a semiconductor chip; an encapsulation layer at least partially encapsulating the semiconductor chip, the encapsulation layer having a receiving region configured to receive an electronic device, the receiving region including a cavity; and an electronic device disposed in the receiving region.

The electronic device may be disposed in the cavity.

The chip arrangement may further include a lid attached to the encapsulation layer and sealing the cavity.

The lid may be attached to the encapsulation layer via an adhesive.

The lid may include, or may consist of, at least one material selected from a group of materials, the group consisting of: a glass material, a ceramic material; a metal or metal alloy; and a polymer material.

An active area of the electronic device may face the lid.

The chip arrangement may further include a gap disposed between the electronic device and the lid.

The electronic device may be spaced apart from at least one sidewall of the cavity.

The electronic device may be spaced apart from sidewalls of the cavity.

The electronic device may be attached to a wall of the cavity via a mechanically decoupling material.

The mechanically decoupling material may include, or may be, an adhesive.

The electronic device may be disposed over the cavity and may be configured to seal the cavity.

The active side of the electronic device may face the cavity.

The electronic device may be electrically coupled to the semiconductor chip.

The cavity may be disposed over the semiconductor chip.

The encapsulation layer may include, or may consist of, a material different from the semiconductor chip.

The encapsulation layer may include, or may consist of, a molding material.

At least one wall of the cavity may be coated at least partially with a sealing material.

The sealing material may include, or may consist of, at least one material selected from the following group of materials, the group consisting of: a ceramic material; a metal or metal alloy; and a polymer material.

The semiconductor chip may be disposed at a first side of the encapsulation layer and the cavity may be disposed at a second side of the encapsulation layer opposite the first side.

The semiconductor chip and the cavity may be disposed at a same side of the encapsulation layer.

The chip arrangement may further include a redistribution layer electrically coupled to the electronic device.

The redistribution layer may be disposed at least partially in the cavity.

The chip arrangement may further include at least one bonding wire disposed in the cavity and electrically coupling the electronic device to the redistribution layer.

The chip arrangement may further include at least one through-via disposed in the encapsulation layer and electrically coupled to the redistribution layer.

The semiconductor chip may be disposed at a first side of the encapsulation layer, the cavity may be disposed at a second side of the encapsulation layer opposite the first side, and the electronic device may be disposed in the cavity, and the chip arrangement may further include a redistribution layer disposed at least partially in the cavity and electrically coupled to the electronic device, and at least one through-via disposed in the encapsulation layer and electrically coupled to the redistribution layer.

At least one through-via may extend from the first side of the encapsulation layer to the second side of the encapsulation layer.

A first part of the redistribution layer may be disposed in the cavity, a second part of the redistribution layer may be disposed over the second side of the encapsulation layer outside the cavity, and the at least one through-via may extend from the first side of the encapsulation layer to the second part of the redistribution layer.

The at least one through-via may extend from the first side of the encapsulation layer to the cavity.

The redistribution layer may be disposed in the cavity, and the at least one through-via may extend from the first side of the encapsulation layer to the redistribution layer disposed in the cavity.

The chip arrangement may further include at least one bonding wire disposed in the cavity and electrically coupling the electronic device to the redistribution layer.

The chip arrangement may further include at least one flip chip interconnect disposed in the cavity and electrically coupling the electronic device to the redistribution layer.

The semiconductor chip may be disposed at a first side of the encapsulation layer, the cavity may be disposed at a second side of the encapsulation layer opposite the first side, and the electronic device may be disposed in the cavity, and the chip arrangement may further include at least one through-via disposed in the encapsulation layer between the semiconductor chip and the cavity and electrically coupled to the semiconductor chip and the electronic device.

The chip arrangement may further include a redistribution layer disposed in the cavity and electrically coupled to the at least one through-via and the electronic device.

The chip arrangement may further include at least one flip chip interconnect disposed in the cavity and electrically coupling the electronic device to the redistribution layer.

The semiconductor chip may be disposed at a first side of the encapsulation layer, the cavity may be disposed at a second side of the encapsulation layer opposite the first side, and the electronic device may be disposed in the cavity, and the chip arrangement may further include at least one flip chip interconnect disposed between the semiconductor chip and the electronic device and electrically coupling the electronic device to the semiconductor chip.

The at least one flip chip interconnect may be in contact with a backside of the semiconductor chip.

The cavity may be disposed laterally adjacent to the semiconductor chip.

The semiconductor chip and the cavity may be disposed at a same side of the encapsulation layer, and the electronic device may be disposed in the cavity, and the chip arrangement may further include a redistribution layer disposed at least partially in the cavity and electrically coupled to the electronic device.

The redistribution layer may be electrically coupled to the semiconductor chip.

The chip arrangement may further include at least one bonding wire disposed in the cavity and electrically coupling the electronic device to the redistribution layer.

The chip arrangement may further include at least one flip chip interconnect disposed in the cavity and electrically coupling the electronic device to the redistribution layer.

The electronic device may be attached to the encapsulation layer along a perimeter of the cavity.

The electronic device may be attached to the encapsulation layer along the perimeter of the cavity by means of an anisotropic conducting adhesive.

The electronic device may be connected to the redistribution layer by means of at least one solder flip chip interconnect, e.g. a plurality of solder flip chip interconnects, which may be disposed along the perimeter of the cavity.

An underfill layer may be disposed between the electronic device and the encapsulation layer along the perimeter of the cavity. The underfill layer may fill a gap between the electronic device and the encapsulation layer. The at least one solder flip chip interconnect may be surrounded by the underfill layer.

The semiconductor chip may be disposed at a first side of the encapsulation layer, and the cavity may be disposed at a second side of the encapsulation layer opposite the first side, and the chip arrangement may further include at least one through-via disposed in the encapsulation layer and extending from the first side of the encapsulation layer to the second of the encapsulation layer, and at least one bonding wire electrically coupled to the electronic device and the at least one through-via.

The chip arrangement may further include a redistribution layer disposed over the second side of the encapsulation layer and electrically coupled to the at least one bonding wire and the at least one through-via.

The electronic device may include, or may be, at least one of the following: a semiconductor chip; a micro-electromechanical system; an oscillator; and a sensor.

The chip arrangement may be configured as a chip package.

The chip arrangement may be configured as an embedded wafer level ball grid array package.

According to various examples described herein, a chip package may be provided. The chip package may include: a semiconductor chip; an encapsulation layer at least partially encapsulating the semiconductor chip; a cavity disposed in the encapsulation layer; and an electronic device disposed in the cavity and electrically coupled to the semiconductor chip.

The semiconductor chip may be disposed at a frontside of the chip package and the cavity may be disposed at a backside of the chip package.

The semiconductor chip and the cavity may be disposed at a frontside of the package.

The chip package may further include a lid attached to the encapsulation layer along a perimeter of the cavity.

The chip package may be configured as an embedded wafer level ball grid array package.

According to various examples described herein, a chip package may be provided. The chip package may include: a semiconductor chip; an encapsulation layer at least partially encapsulating the semiconductor chip; a cavity disposed in the encapsulation layer; and an electronic device disposed over the cavity and configured to seal the cavity, and electrically coupled to the semiconductor chip.

An active side of the electronic device may face the cavity.

The semiconductor chip may be disposed at a frontside of the chip package and the cavity may be disposed at a backside of the chip package.

At least one wall of the cavity may be coated at least partially with a sealing material.

The chip package may be configured as an embedded wafer level ball grid array package.

According to various examples described herein, an embedded wafer level ball grid array (eWLB) package may be provided. The eWLB package may include: a semiconductor chip; encapsulation material at least partially encapsulating the semiconductor chip; a cavity disposed in the encapsulating material; and an electronic device disposed in the cavity and electrically coupled to the semiconductor chip.

According to various examples described herein, a method for manufacturing a chip arrangement may be provided. The method may include: providing a semiconductor chip; forming an encapsulation layer to at least partially encapsulate the semiconductor chip; forming a cavity in the encapsulation layer; and disposing an electronic device in or over the cavity.

Forming the encapsulation layer may include, or may consist of, a molding process.

Forming the cavity in the encapsulation layer may include, or may consist of, forming the cavity during the molding process using a predeterminable mold tool.

Forming the cavity in the encapsulation layer may include, or may consist of, forming the cavity by removing material of the encapsulation layer after forming the encapsulation layer.

Forming the cavity in the encapsulation layer may include, or may consist of, embedding a sacrificial material in the encapsulation layer when forming the encapsulation layer, and subsequently removing the sacrificial material.

The sacrificial material may have the shape of the cavity.

Various examples and aspects described in the context of one of the chip arrangements or chip packages or methods described herein may be analogously valid for the other chip arrangements or chip packages or methods described herein.

While various aspects have been particularly shown and described with reference to these aspects of this disclosure, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A chip arrangement, comprising:
a semiconductor chip;
an encapsulation layer at least partially encapsulating the semiconductor chip, the encapsulation layer having a receiving region configured to receive an electronic device, the receiving region comprising a cavity; and
an electronic device disposed in the receiving region.

2. The chip arrangement of claim 1, wherein the electronic device is disposed in the cavity.

3. The chip arrangement of claim 2, further comprising a lid attached to the encapsulation layer and sealing the cavity.

4. The chip arrangement of claim 3, wherein an active area of the electronic device faces the lid.

5. The chip arrangement of claim 3, further comprising a gap disposed between the electronic device and the lid.

6. The chip arrangement of claim 3, wherein the electronic device is spaced apart from at least one sidewall of the cavity.

7. The chip arrangement of claim 2, wherein the electronic device is attached to a wall of the cavity via a mechanically decoupling material.

8. The chip arrangement of claim 1, wherein the electronic device is disposed over the cavity and configured to seal the cavity.

9. The chip arrangement of claim 8, wherein an active side of the electronic device faces the cavity.

10. The chip arrangement of claim 1, wherein the electronic device is electrically coupled to the semiconductor chip.

11. The chip arrangement of claim 1, wherein at least one wall of the cavity is coated at least partially with a sealing material.

12. The chip arrangement of claim 1, wherein the semiconductor chip is disposed at a first side of the encapsulation layer and the cavity is disposed at a second side of the encapsulation layer opposite the first side.

13. The chip arrangement of claim 1, wherein the semiconductor chip and the cavity are disposed at a same side of the encapsulation layer.

14. The chip arrangement of claim 1, further comprising a redistribution layer electrically coupled to the electronic device.

15. The chip arrangement of claim 14, wherein the redistribution layer is disposed at least partially in the cavity.

16. The chip arrangement of claim 14, further comprising at least one bonding wire disposed in the cavity and electrically coupling the electronic device to the redistribution layer.

17. The chip arrangement of claim 14, further comprising at least one through-via disposed in the encapsulation layer and electrically coupled to the redistribution layer.

18. The chip arrangement of claim 14, further comprising at least one flip chip interconnect disposed in the cavity and electrically coupling the electronic device to the redistribution layer.

19. The chip arrangement of claim 8, wherein the electronic device is attached to the encapsulation layer along a perimeter of the cavity.

20. The chip arrangement of claim 19, wherein the electronic device is attached to the encapsulation layer along the perimeter of the cavity by means of an anisotropic conducting adhesive.

21. The chip arrangement of claim 1, configured as a chip package.

22. A chip package, comprising:
a semiconductor chip;
an encapsulation layer at least partially encapsulating the semiconductor chip;
a cavity disposed in the encapsulation layer; and
an electronic device disposed in the cavity and electrically coupled to the semiconductor chip.

23. The chip package of claim 22, further comprising a lid attached to the encapsulation layer along a perimeter of the cavity.

24. A chip package, comprising:
a semiconductor chip;
an encapsulation layer at least partially encapsulating the semiconductor chip;
a cavity disposed in the encapsulation layer; and
an electronic device disposed over the cavity and configured to seal the cavity, and electrically coupled to the semiconductor chip.

25. The chip package of claim 24, wherein an active side of the electronic device faces the cavity.

26. A method for manufacturing a chip arrangement, the method comprising:
providing a semiconductor chip;
forming an encapsulation layer to at least partially encapsulate the semiconductor chip;
forming a cavity in the encapsulation layer; and
disposing an electronic device in or over the cavity.

27. The method of claim 26, wherein forming the encapsulation layer comprises a molding process.
